(19) United States
(12) Patent Application Publication
(10) Pub. No.: US 2015/0294929 A1
(43) Pub. Date: Oct. 15, 2015

(54) SEMICONDUCTOR DIE PACKAGE AND METHOD OF ASSEMBLING SAME

(71) Applicants: Zhigang Bai, Tianjin (CN); Zhijie Wang, Tianjin (CN); Jinzhong Yao, Tianjin (CN)

(72) Inventors: Zhigang Bai, Tianjin (CN); Zhijie Wang, Tianjin (CN); Jinzhong Yao, Tianjin (CN)

(21) Appl. No.: 14/552,491

(22) Filed: Nov. 25, 2014

(30) Foreign Application Priority Data
Apr. 11, 2014 (CN) 201410145465.6

(51) Int. Cl. H01L 23/495; H01L 21/48; H01L 21/56; H01L 23/00; H01L 23/31

(52) U.S. Cl. CPC H01L 23/49555; H01L 23/4951; H01L 24/49; H01L 23/3107; H01L 24/85; H01L 21/565; H01L 21/4842; H01L 2224/48247; H01L 2224/48106; H01L 2224/85801

(57) ABSTRACT

A semiconductor die package is assembled from a lead frame having lead fingers with a bonding end adjacent a die flag, and an elongate region extending away from the die flag. A semiconductor die is mounted on the die flag and electrodes of the semiconductor die are electrically connected to the bonding ends with bond wires. Each elongate region is bent into an external connector lead with mounting feet. The elongate region of each of the lead fingers protrudes from a housing formed from a mold compound. The mold compound extends from the housing to provide insulated support fingers molded to the external connector leads.

### BACKGROUND OF THE INVENTION

The present invention relates generally to semiconductor die packages and, more particularly, to a semiconductor die package having insulated outer leads or support fingers.

Semiconductor die packaging provides for suitable external electrical connections and protection of a semiconductor die against mechanical and environmental stresses. Continued progress in reduction of the size of the semiconductor dies and increased functionality and complexity of the circuits formed in the dies require size reduction of the packaging.

One typical type of semiconductor die package is a Quad Flat Package (QFP), which is formed with a semiconductor die mounted to a lead frame. The lead frame is formed from a sheet of metal that has a die attach pad often called a flag and struts that attach the flag to a frame. The lead frame has lead fingers that surround the flag. Electrodes of the die are electrically connected to the proximal ends of the lead fingers with bond wires to provide a means of easily electrically connecting the die to circuit boards and the like. After the electrodes and pads are connected, the semiconductor die and the bond wires are encapsulated in a mold compound leaving only sections of the lead fingers exposed. These exposed or external leads are cut from the frame of the lead frame (singulated) and bent for ease of connection to a circuit board.

The inherent structure and size of QFP packages results in limiting the number of external leads, and therefore the number of package external electrical connections, that can be used for a specific QFP package size. However, the lead width and lead pitch can be reduced to allow for an increased number of leads. Such a reduction in pitch may cause inter lead shorting and the reduced lead width may result in deformation or bending of the relatively thin leads. Accordingly, it would be advantageous to reduce the lead pitch and at the same time, reduce the risk of inter lead shorting.

### BRIEF DESCRIPTION OF THE DRAWINGS

The invention, together with objects and advantages thereof, may best be understood by reference to the following description of preferred embodiments together with the accompanying drawings in which:

FIG. 1 is a partial plan view of a lead frame sheet according to a first embodiment of the present invention;

FIG. 2 is a plan view of a lead frame assembly that is part of the lead frame sheet of FIG. 1 after semiconductor die population;

FIG. 3 is a plan view of a wire bonded lead frame assembly formed from the lead frame assembly of FIG. 2;

FIG. 4 is a cross-sectional side view through 4-4′ of the wire bonded lead frame assembly of FIG. 3;

FIG. 5 is a cross-sectional side view of a molding and forming jig when clamping the wire bonded lead frame assembly of FIG. 3 according to the first embodiment of the present invention;

FIG. 6 is a side view of a semiconductor die package according to the first embodiment of the present invention;

FIG. 7 is a plan view of the semiconductor die package of FIG. 6;

FIG. 8 is a cross-sectional side view of a molding and forming jig when clamping the wire bonded lead frame assembly of FIG. 3 according to a second embodiment of the present invention;

FIG. 9 is a side view of a semiconductor die package according to the second embodiment of the present invention;

FIG. 10 is a plan view of the semiconductor die package of FIG. 9;

FIG. 11 is a cross-sectional side view of a molding and forming jig when clamping the wire bonded lead frame assembly of FIG. 3 according to a third embodiment of the present invention;

FIG. 12 is a side view of a semiconductor die package according to the third embodiment of the present invention;

FIG. 13 is a plan view of the semiconductor die package of FIG. 11;

FIG. 14 is a partial plan view of a lead frame sheet according to a fourth embodiment of the present invention;

FIG. 15 is an end view of a group of mounting feet according to a fifth embodiment of the present invention;

FIG. 16 is a flow chart illustrating a method of assembling a semiconductor die package in accordance with an embodiment of the present invention.

### DETAILED DESCRIPTION OF PREFERRED EMBODIMENTS

The detailed description set forth below in connection with the appended drawings is intended as a description of presently preferred embodiments of the invention, and is not intended to represent the only forms in which the present invention may be practised. It is to be understood that the same or equivalent functions may be accomplished by different embodiments that are intended to be encompassed within the spirit and scope of the invention. In the drawings, like numerals are used to indicate like elements throughout. Furthermore, terms “comprises,” “comprising,” or any other variation thereof, are intended to cover a non-exclusive inclusion, such that module, circuit, device components, structures and method steps that comprises a list of elements or steps does not include only those elements but may include other elements or steps not expressly listed or inherent to such module, circuit, device components or steps. An element or step proceeded by “comprises . . . a” does not, without more constraints, preclude the existence of additional identical elements or steps that comprises the element or step.

In one embodiment, the present invention provides a semiconductor die package comprising a die flag and lead fingers surrounding the die flag. Each of the lead fingers has a bonding end adjacent the die flag and an elongate region extending away from the die flag. A semiconductor die is mounted on the die flag and bond wires electrically connect electrodes of the die to the bonding end of each of the lead fingers. A mold compound forms a housing that covers the die, bond wires, bonding ends of the lead fingers, and the die flag. The elongate region of each of the lead fingers protrudes from the housing to provide external connector leads for the package. The mold compound extends from the housing to provide insulated support fingers molded to the external connector leads.

In another embodiment, the present invention provides a method of assembling a semiconductor die package. The method comprises providing a lead frame having a surrounding frame that surrounds a die flag. The lead frame has tie bars extending inwardly from the surrounding frame and supporting the die flag, and there are lead fingers surrounding the die flag, each lead finger having a bonding end adjacent the die flag and an elongate region extending away from the die flag towards the outer fame. Outer dam bars bridge adjacent free ends of the elongate regions and inner dam bars support the lead fingers from the outer surrounding frame. The inner dam bars define an external periphery package housing outline for a periphery other than regions between adjacent elongate regions. The method also comprises mounting a semiconductor die on the die flag and electrically connecting electrodes of the semiconductor die to the bonding end of each of the lead fingers with bond wires. There is also performed forming each elongate region into external connector leads with mounting feet at free ends thereof. The elongate region of each of the lead fingers protrudes from the housing to provide the external connector leads for the package. During the molding process some of the mold compound flows from the molding chamber between adjacent external connector leads to provide insulated support fingers molded to the external connector leads.

In a further embodiment, the present invention provides a lead frame sheet with an array of lead frames formed therein. Each of the lead frames includes a surrounding frame that surrounds a die flag, and tie bars extending inwardly from the surrounding frame and supporting the die flag. Each of the lead frames also includes lead fingers surrounding the die flag, each lead finger having a bonding end adjacent the die flag and an elongate region extending away from the die flag towards the outer fame. Outer dam bars bridge adjacent free ends of the elongate regions and inner dam bars supporting the lead fingers from the outer surrounding frame. The inner dam bars define a external periphery package housing outline for a periphery other than regions between adjacent elongate regions

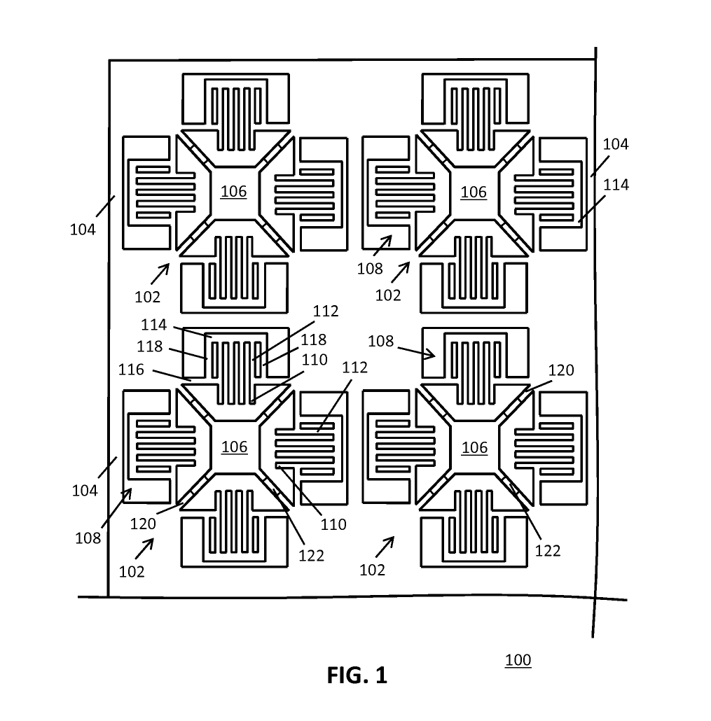

Referring now to FIG. 1, a partial plan view of a lead frame sheet 100 according to a first embodiment of the present invention is shown. The lead frame sheet 100 is typically formed from metal such as copper and thus is both thermally and electrically conducive. The lead frame sheet 100 has a plurality of lead frames 102 in an array and the lead frames 102 are typically formed by punching or cutting out regions of the lead frame sheet 100. Each of the lead frames 102 has an outer surrounding frame 104 that surrounds a centrally located die flag 106 that is supported by the surrounding frame 104.

Each one of the lead frames 102 also includes lead fingers 108 that surround the die flag 106, each having a bonding end 110 adjacent the die flag 106 and an elongate region 112 extending away from the die flag 106 towards the outer surrounding frame 104. Respective outer dam bars 114 bridge adjacent free ends of the elongate regions 112 and in combination with inner dam bars 116 support the lead fingers 108 from the outer surrounding frame 104. In this embodiment, the inner dam bars 116 do not bridge across the lead fingers 108 and there are also dummy leads 118 that provide additional support as will be apparent to a person skilled in the art.

In this embodiment there are tie bars 120 that extend inwardly from the surrounding frame 104 and support the die flag 106. The tie bars 120 each have an angled section 122 that is angled to form a down-set relationship between the die flag 106 and surrounding frame 104.

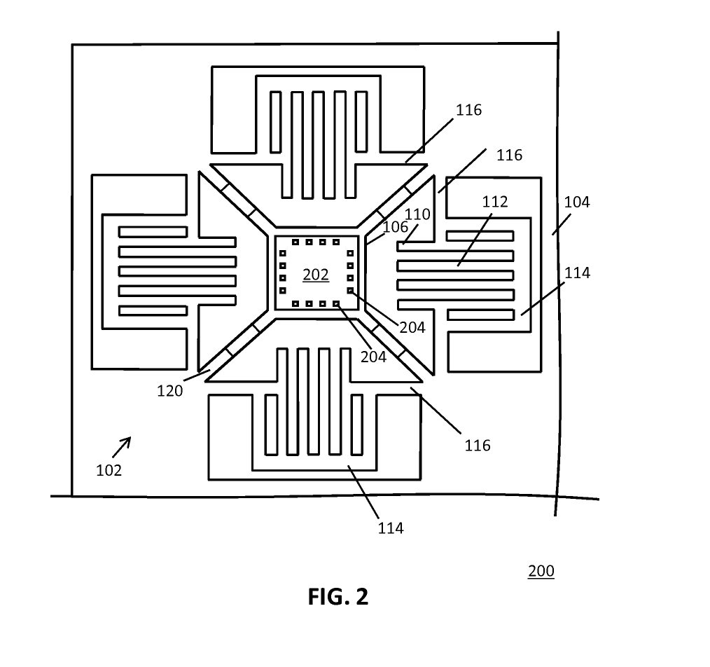

FIG. 2 is a plan view of a lead frame assembly 200 which is part of the lead frame sheet 100 after semiconductor die population. Mounted to the die flag 106 is a semiconductor die 202 that has electrodes 204 for external connection.

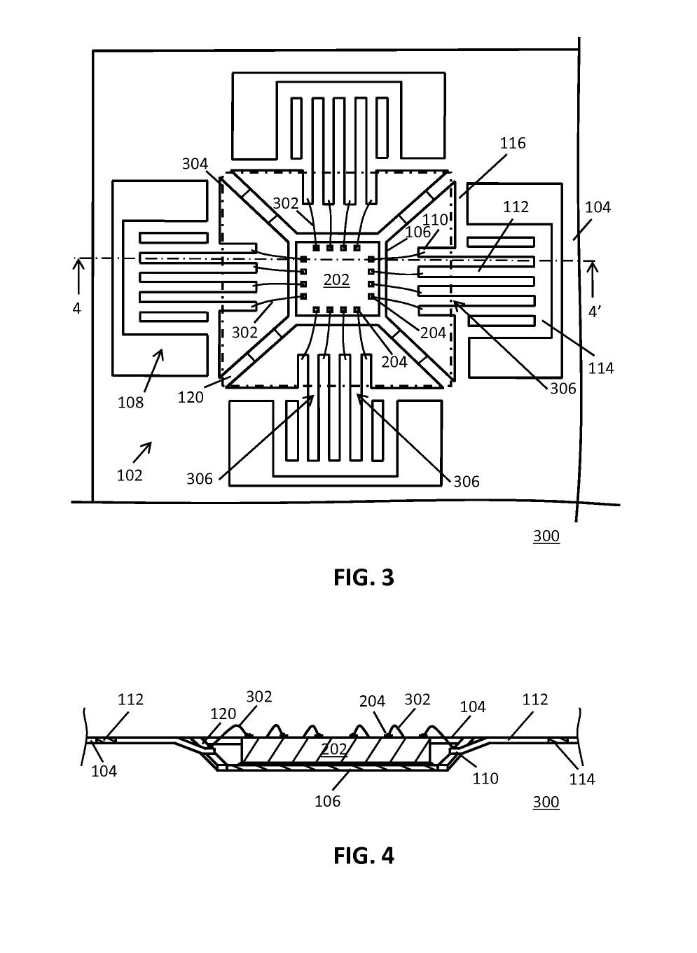

FIG. 3 is a plan view of a wire bonded lead frame assembly 300 formed from the lead frame assembly 200. The wire bonded lead frame assembly 300 includes bond wires 302 that electrically connect the electrodes 204 of the semiconductor die 202 to the bonding end 110 of each of the lead fingers 108. Also, shown in phantom is a periphery of a package housing outline 304 formed from a mold compound that will be described below. The package housing outline 304 is bounded by the inner dam bars 116, however, the inner dam bars 116 do not bridge the across the lead fingers 108. A result, housing molding outlets 306 are provided between adjacent lead fingers 108 as will be described below.

FIG. 4 is a cross-sectional side view through 4-4′ of the wire bonded lead frame assembly 300. In this illustration, the down-set relationship between the die flag 106 and surrounding frame 104 is shown. Also shown are the elongate region 112 of the lead fingers 108 are planar with the outer surrounding frame 104.

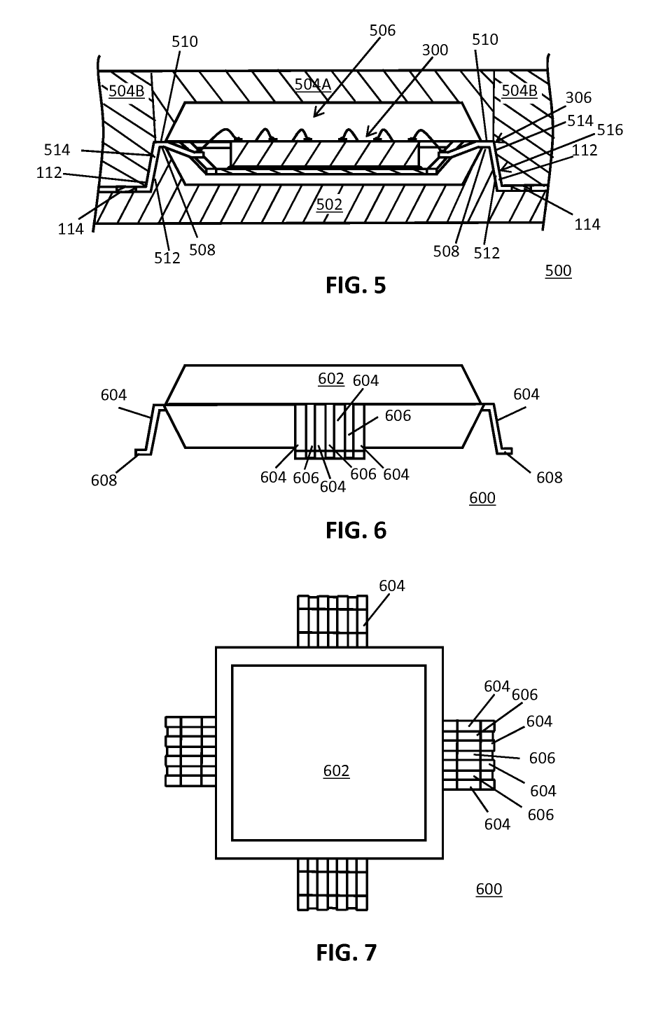

FIG. 5 is a cross-sectional side view of a molding and forming jig 500 when clamping the wire bonded lead frame assembly 300 according to the first embodiment of the present invention. The jig 500 includes an anvil 502 and complementary upper members 504A, 504B in which the anvil 502 and upper member 504A together form a housing mold cavity 506. The jig 500 also has co-acting inner dam bar clamping members 508, 510 and co-acting lead finger forming (reshaping) surfaces 512, 514 formed from the anvil 502 and member 504B. The upper members 504A, 504B are movable relative to each other so that initially the anvil 502 and upper member 504A are brought together to form the housing mold cavity 506 in which the inner dam bar clamping members 508, 510 clamp the inner dam bars 116 for later package housing outline 304 formation. Once the inner dam bars 116 are clamped, the upper member 504B moves towards the anvil 502 so that the surfaces 512, 514 co-act to bend (form) the elongate regions 112 of the lead fingers 108. Furthermore, surfaces 512, 514, outer dam bars 114 and spaces between adjacent elongate regions 112 form external molding cavities 516 accessible from the housing mold cavity 506 through the housing molding outlets 306.

In operation a mold compound is deposited into the housing mold cavity 506 to cover the semiconductor die 202, the bond wires 302, each bonding end 110 of the lead fingers 108 and the die flag 106. Furthermore, during molding some the mold compound flows into the housing mold cavity 506 through the housing molding outlets 306 and into the external molding cavities 516.

Referring to FIGS. 6 and 7, respective side and plan views of a semiconductor die package 600 according to the first embodiment of the present invention are shown. The semiconductor die package 600 is the wire bonded lead frame assembly 300 that has undergone an encapsulation process whilst being clamped in the molding and forming jig 500. Furthermore the semiconductor die package 600 has been cut (singulated) and trimmed by removal of the outer dam bars 114 and dummy leads 118 from the lead fingers 108, severing of the tie bars 120 from the die flag 106 and also severing of the inner dam bars 116 from the lead fingers 108.

The semiconductor die package 600 includes the mold compound that forms a housing 602 that covers the semiconductor die 202, the bond wires 302, each bonding end 110 of the lead fingers 108 and the die flag 106. In addition, the elongate region 112 of each of the lead fingers 108 protrudes from the housing 602 to provide external connector leads 604 for the package 600. The mold compound that flowed into the external molding cavities 516 extends from the housing 602 to provide insulated support fingers 606 molded to the external connector leads 604.

The co-acting lead finger forming (reshaping) surfaces 512, 514 have bent free ends of the external connector leads 604 to form mounting feet 608. Furthermore, in this embodiment as illustrated the insulated support fingers 606 are coplanar with respective adjacent regions of the external connector leads 604.

In this embodiment, the insulated support fingers 606 extend along a total length of the external connector leads 604. However, in some embodiments the insulated support fingers 606 need not extend total length of the external connector leads 604 and for instance my terminate before the mounting feet 608.

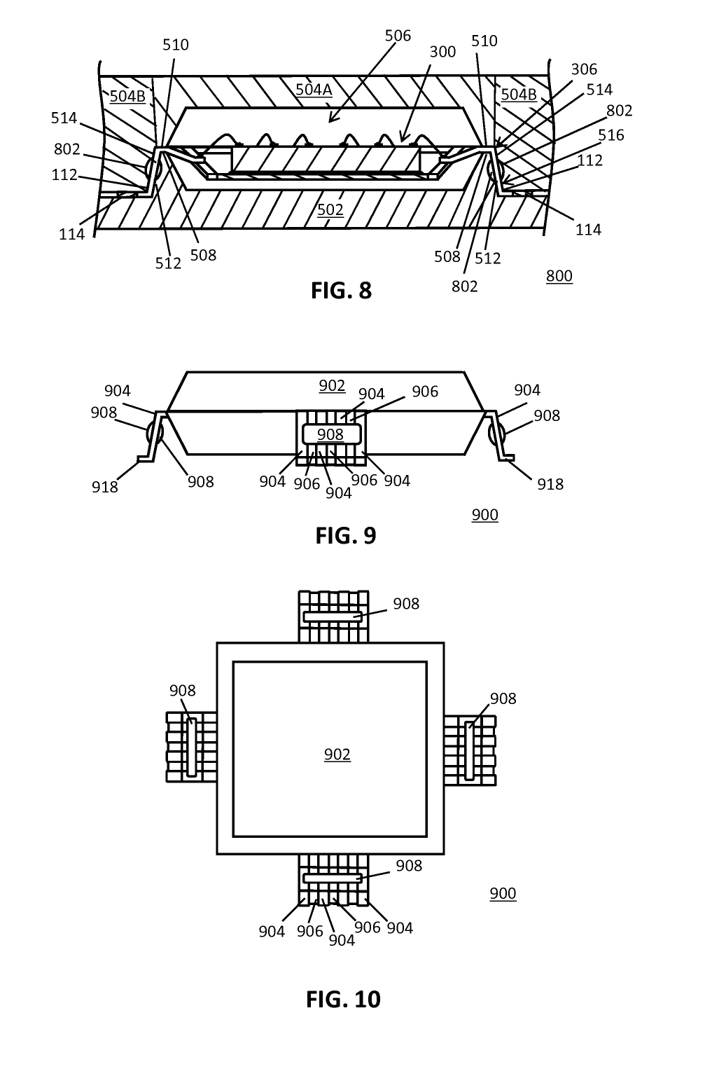

FIG. 8 is a cross-sectional side view of a molding and forming jig 800 when clamping the wire bonded lead frame assembly 300 according to a second embodiment of the present invention. The jig 800 is similar to the jig 500 and to avoid repetition only the differences will be described. In this embodiment the external molding cavities 516 are modified to include bridging cavities 802. In operation, after bending and the elongate regions 112 of the lead fingers 108, a mold compound is deposited into the housing mold cavity 506 to cover the semiconductor die 202, the bond wires 302, each bonding end 110 of the lead fingers 108 and the die flag 106. During molding some the mold compound flows into the housing mold cavity 506 through the housing molding outlets 306 and into both the external molding cavities 516 and bridging cavities 802.

FIGS. 9 and 10 illustrate respective side and plan views of a semiconductor die package 900 according to the second embodiment of the present invention. The semiconductor die package 900 is the wire bonded lead frame assembly 300 that has undergone an encapsulation process whilst being clamped in the molding and forming jig 800. Furthermore the semiconductor die package 900 has been cut (singulated) and trimmed by removal of the outer dam bars 114 and dummy leads 118 from the lead fingers 108, severing of the tie bars 120 from the die flag 106 and also severing of the inner dam bars 116 from the lead fingers 108.

The semiconductor die package 900 includes the mold compound that forms a housing 902 that covers the semiconductor die 202, the bond wires 302, each bonding end 110 of the lead fingers 108 and the die flag 106. In addition, the elongate region 112 of each of the lead fingers 108 protrudes from the housing 902 to provide external connector leads 904 for the package 900. The mold compound that flowed into the external molding cavities 516 extends from the housing 602 to provide insulated support fingers 906 molded to the external connector leads 904. Also, the mold compound that flowed into the bridging cavities 802 forms a respective insulated cross member 908 associated with and molded to a group of the external connector leads 604. Furthermore, each respective cross member 908 is normal to longitudinal axes of the group of external connector leads 604 and each cross member 908 is integral with a group of the insulated support fingers 906.

In this embodiment, the insulated support fingers 906 extend along a total length of the external connector leads 904. However, in some embodiments the insulated support fingers 906 need not extend total length of the external connector leads 904 and for instance my terminate before reaching mounting feet 918 of the external connector leads 904.

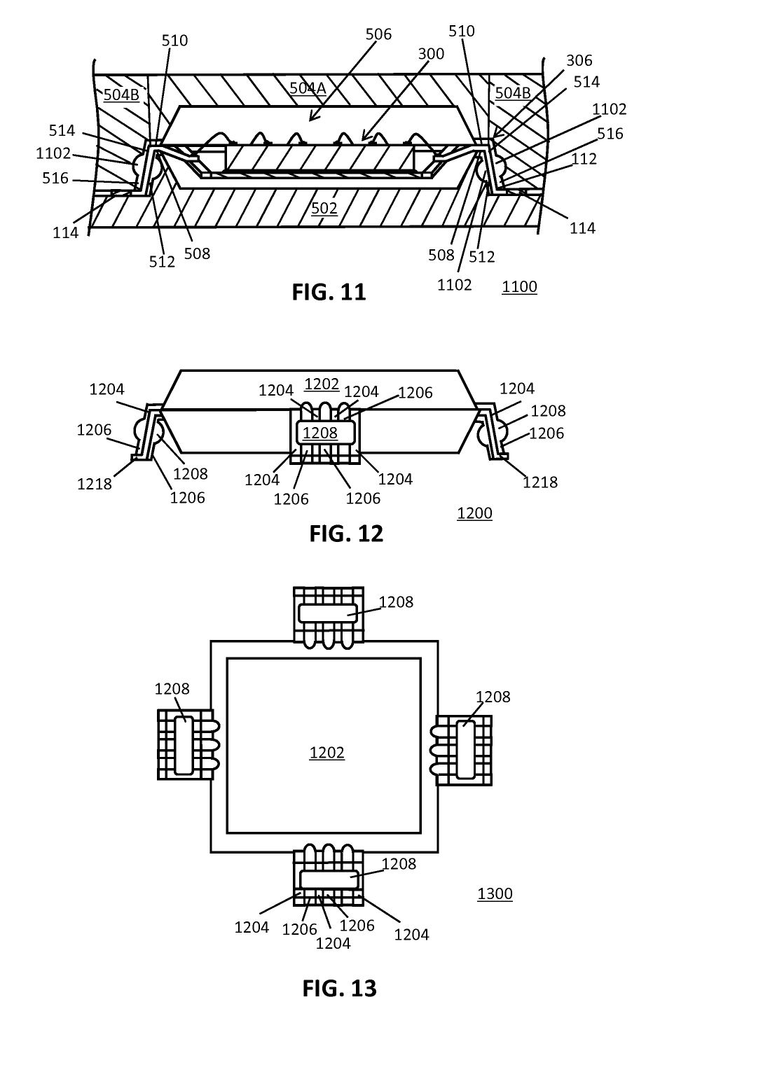

Referring to FIG. 11, a cross-sectional side view of a molding and forming jig 1100 when clamping the wire bonded lead frame assembly 300 according to a third embodiment of the present invention is shown. The jig 1100 is similar to the jig 500 and to avoid repetition only the differences will be described. In this embodiment the jig 1100 is modified to increase the size of the external molding cavities 516 which include bridging cavities 1102.

In operation, after bending and the elongate regions 112 of the lead fingers 108, a mold compound is deposited into the housing mold cavity 506 to cover the semiconductor die 202, the bond wires 302, each bonding end 110 of the lead fingers 108 and the die flag 106. During molding some the mold compound flows into the housing mold cavity 506 through the housing molding outlets 306 and into both the external molding cavities 516 and bridging cavities 1102.

Referring to FIGS. 12 and 13, respective side and plan views of a semiconductor die package 1200 according to the third embodiment of the present invention are shown. The semiconductor die package 1200 is the wire bonded lead frame assembly 300 that has undergone an encapsulation process whilst being clamped in the molding and forming jig 1100. Furthermore the semiconductor die package 1200 has been cut (singulated) and trimmed by removal of the outer dam bars 114 and dummy leads 118 from the lead fingers 108, severing of the tie bars 120 from the die flag 106 and also severing of the inner dam bars 116 from the lead fingers 108.

The semiconductor die package 1200 includes the mold compound that forms a housing 1202 that covers the semiconductor die 202, the bond wires 302, each bonding end 110 of the lead fingers 108 and the die flag 106. In addition, the elongate region 112 of each of the lead fingers 108 protrudes from the housing 1202 to provide external connector leads 1204 for the package 1200. The mold compound that flowed into the external molding cavities 516 extends from the housing 602 to provide insulated support fingers 1206 molded to the external connector leads 904. The insulated support fingers 1206 are thicker than the external connector leads 1204 and cover regions of both a top and opposite lower surface of the external connector leads 1204.

Also, the mold compound that flowed into the bridging cavities 1102 forms a respective insulated cross member 1208 associated with and molded to a group of the external connector leads 604. Furthermore, each respective cross member 1208 is normal to longitudinal axes of the group of external connector leads 604 and each cross member 1208 is integral with a group of the insulated support fingers 1206.

In this embodiment, the insulated support fingers 1206 extend along a total length of the external connector leads 1204. However, in some embodiments the insulated support fingers 1206 need not extend total length of the external connector leads 1204 and for instance my terminate before reaching mounting feet 1218 of the external connector leads 1204.

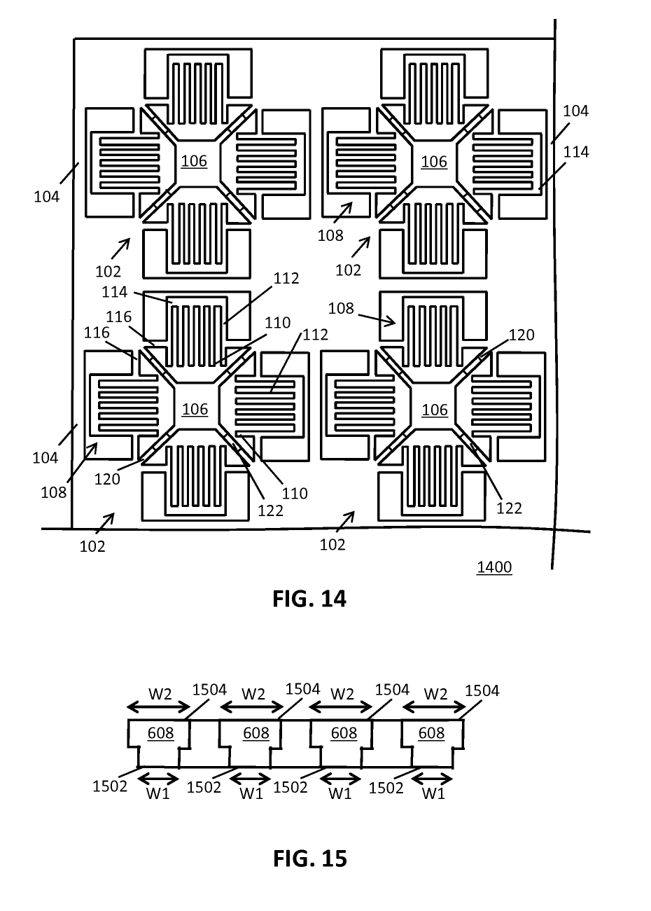

Referring to FIG. 14, a partial plan view of a lead frame sheet 1400 according to a fourth embodiment of the present invention is shown. The lead frame sheet 1400 is essentially the same as the lead frame sheet 100 with the exception of the elimination of the dummy leads 118. The lead frame sheet 1400 can be populated by semiconductor dies 202 and formed into a semiconductor package as described in any of the above embodiments.

FIG. 15 is an end view a group of the mounting feet 608 according to a fifth embodiment of the present invention. The mounting feet 608 each have a base 1502 and a corresponding opposite upper surface 1504 and as shown each base 1502 has a width W1 that is narrower than the width W2 of the corresponding opposite upper surface 1504.

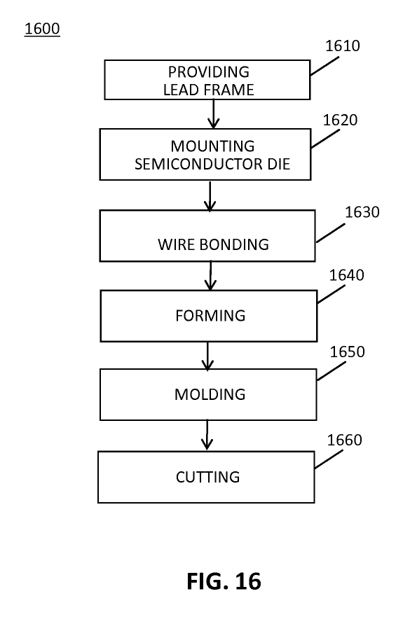

Referring to FIG. 16, a flow chart of a method 1600 of assembling a semiconductor die package according to an embodiment of the present invention is shown. The method 1600 includes, at block 1610, providing a lead frame such as such one of the lead frames 102 of the lead frame sheet 100 or 1400. At a block 1620, the method 1600 performs mounting a semiconductor die, such as die 202, on the die flag 106 and that a block 1630 there is performed a process of selectively wire bonding electrodes 204 of the semiconductor die 202 to the bonding end 110 of each of the lead fingers 108. As a result the wire bonded lead frame assembly 300 is formed and this assembly is placed in a molding and forming jig such as one of jigs 500, 800 or 1100. At a block 1640 the jigs anvil and complementary upper member are brought together to thereby form a housing mold cavity and thus forming (bending) each elongate region 112 into external connector leads with mounting feet at free ends of the leads.

The method 1600 at a block 1650 includes performing a molding process to form a housing from a mold compound deposit. The molding process injects or presses a mold compound into the housing mold cavity 506 so that the mold compound covers the semiconductor die 202, the bond wires 302, each bonding end 110 and the die flag 106. During the molding process the inner dam bars 116 form a partial external periphery of molding chamber for the housing (e.g., housing 602, 902, 1202). In addition, the elongate region of each of the lead fingers 108 protrudes from the housing to provide the external connector leads for the package, and during the molding process some of the mold compound flows from the molding chamber 506 between adjacent external connector leads to provide insulated support fingers molded to the external connector leads. Furthermore, during the molding process the flow of the mold compound between adjacent external connector leads is retained by the outer dam bars 114. Finally the method 1600 is complete after a block 1660 performs a cutting (singulating) process to sever the outer and inner dam bars 114, 116 and tie bars 120 which results in a completed package such as semiconductor die package 600, 900 or 1200.

Advantageously, the present invention provides for strengthening the external leads of a semiconductor die package by use of the insulated support fingers, which can be further strengthened by the insulated cross members. As a result, the present invention at least alleviates inter lead shorting caused by a reduction in external lead pitch and the reduced lead width. The insulated support fingers and insulated cross members may also alleviate deformation or undesirable bending of the external leads. In addition, because the base of the mounting feet has a width narrower than the width of corresponding opposite upper surface, this feature can also reduce the possibility of solder shorts when the semiconductor package is mounted onto a circuit board.

The description of the preferred embodiments of the present invention has been presented for purposes of illustration and description, but is not intended to be exhaustive or to limit the invention to the forms disclosed. It will be appreciated by those skilled in the art that changes could be made to the embodiments described above without departing from the broad inventive concept thereof. It is understood, therefore, that this invention is not limited to the particular embodiment disclosed, but covers modifications within the spirit and scope of the present invention as defined by the appended claims.

1. A semiconductor die package, comprising:
a die flag;
lead fingers surrounding the die flag, each lead finger having a bonding end adjacent the die flag and an elongate region extending away from the die flag;
a semiconductor die mounted on the die flag;
bond wires electrically connecting electrodes of the semiconductor die to the bonding end of each of the lead fingers; and
a mold compound forming a housing that covers the semiconductor die, the bond wires, each bonding end and the die flag,
wherein the elongate region of each of the lead fingers protrudes from the housing to provide external connector leads for the package, and the mold compound extends from the housing to provide insulated support fingers molded to the external connector leads.

2. The semiconductor die package of claim 1, wherein the insulated support fingers extend along a total length of the external connector leads.

3. The semiconductor die package of claim 1, wherein free ends of the external connector leads are bent to form mounting feet.

4. The semiconductor die package of claim 1, wherein the insulated support fingers are coplanar with respective adjacent regions of the external connector leads.

5. The semiconductor die package of claim 1, wherein the mold compound further forms an insulated cross member normal to longitudinal axes of a group of the external connector leads.

6. The semiconductor die package of claim 5, wherein the insulated cross member is molded to the group of external connector leads.

7. The semiconductor die package of claim 6, wherein the insulated cross member is integral with a group of the insulated support fingers.

8. The semiconductor die package of claim 1, wherein the mounting feet each have a base and a corresponding opposite upper surface and wherein each base has a width narrower than the width of corresponding opposite upper surface.

9. A method of assembling a semiconductor die package, the method comprising:
providing a lead frame having (i) a surrounding frame that surrounds a die flag, (ii) tie bars extending inwardly from the surrounding frame and supporting the die flag, (iii) lead fingers surrounding the die flag, each lead finger having a bonding end adjacent the die flag and an elongate region extending away from the die flag towards the outer fame, (iv) outer dam bars bridging adjacent free ends of the elongate regions, and (v) inner dam bars supporting the lead fingers from the outer surrounding frame, wherein the inner dam bars define an external periphery package housing outline for a periphery other than regions between adjacent elongate regions;
mounting a semiconductor die on the die flag;
electrically connecting electrodes of the semiconductor die to the bonding end of each of the lead fingers with bond wires;
forming each elongate region into external connector leads with mounting feet at free ends thereof; and
performing a molding process to form a housing with a mold compound that covers the semiconductor die, the bond wires, and each bonding end and the die flag, wherein during the molding process the inner dam bars form a partial external periphery of a molding chamber for the housing, and
wherein the elongate region of each of the lead fingers protrudes from the housing to provide the external connector leads for the package, and during the molding process some of the mold compound flows from the molding chamber between adjacent external connector leads to provide insulated support fingers molded to the external connector leads.

10. The method of assembling a semiconductor die package of claim 9, wherein the flow of the mold compound between adjacent external connector leads is retained by the outer dam bars.

11. The method of assembling a semiconductor die package of claim 9, wherein the insulated support fingers extend along a total length of the external connector leads.

12. The method of assembling a semiconductor die package of claim 9, wherein the external connector leads are bent to form mounting feet.

13. The method of assembling a semiconductor die package of claim 9, wherein the insulated support fingers are coplanar with respective adjacent regions of the external connector leads.

14. The method of assembling a semiconductor die package of claim 9, wherein the mold compound further forms an insulated cross member normal to longitudinal axes of a group of the external connector leads.

15. The method of assembling a semiconductor die package of claim 14, wherein the insulated cross member is molded to the group of external connector leads.

16. The method of assembling a semiconductor die package of claim 15, wherein the insulated cross member is integral with a group of the insulated support fingers.

17. The method of assembling a semiconductor die package of claim 9, wherein the mounting feet each have a base and a corresponding opposite upper surface and wherein each base has a width narrower than the width of corresponding opposite upper surface.

18. The method of assembling a semiconductor die package of claim 9, wherein the forming of each elongate region into external connector leads and the performing of the molding process is performed with a molding and forming jig.

19. A lead frame sheet with an array of lead frames formed therein, each of the lead frames comprising:
a surrounding frame that surrounds a die flag;
tie bars extending inwardly from the surrounding frame and supporting the die flag;
lead fingers surrounding the die flag, each of the lead fingers having a bonding end adjacent the die flag and an elongate region extending away from the die flag towards the outer fame;
outer dam bars bridging adjacent free ends of the elongate regions; and
inner dam bars supporting the lead fingers from the outer surrounding frame,
wherein the inner dam bars define a external periphery package housing outline for a periphery other than regions between adjacent elongate regions.

20. The lead frame sheet of claim 19, wherein a free end of each said elongate region adjacent a said outer dam bar has a base and a corresponding opposite upper surface and wherein the base has a width narrower than the corresponding opposite upper surface.
